(19) United States
(12) Patent Application Publication
(10) Pub. No.: US 2014/0122010 A1
(43) Pub. Date: May 1, 2014

(54) LCD DRIVER VERIFICATION SYSTEM

(71) Applicant: FREESCALE SEMICONDUCTOR, INC., Austin, TX (US)

(72) Inventors: Kushal Kamal, Noida (IN); Kumar Abhishek, Ghaziabad (IN); Sunny Gupta, Noida (IN)

(73) Assignee: FREESCALE SEMICONDUCTOR, INC., Austin, TX (US)

(21) Appl. No.: 13/665,902

(22) Filed: Oct. 31, 2012

(51) Int. Cl. G01R 31/26; G06F 19/00

(52) U.S. Cl. 702/108

(57) ABSTRACT

A system and method for verifying the electrical behavior of a liquid crystal display (LCD) driver circuit connected to LCD segments of an electronic circuit includes generating test patterns for verifying the LCD driver circuit. The LCD driver circuit generates LCD stimuli in the form of electrical current based on the test patterns. The current is applied to front and back planes of each LCD segment. Root mean square (RMS) voltages of each LCD segment are determined and compared with predetermined threshold values to verify the state of each LCD segment.

### BACKGROUND OF THE INVENTION

The present invention relates generally to liquid crystal display (LCD) driver circuits, and, more particularly, to verification of LCD driver circuits.

Electronic devices including microprocessors, microcontroller units (MCUs), system-on-chips (SOCs), and application specific integrated circuits (ASICs) often include LCD segments for display purposes. The LCD segments are placed at intersections of front and back planes of a LCD display grid. An LCD driver circuit is connected to the front and back planes of each LCD and provides the required voltage to each LCD segment for illumination.

LCD displays need to be accurate, which makes it necessary to verify the operation of the LCD driver circuit. Electronic devices often transition across different modes of operation such as RUN, STANDBY, and STOP, and certain internal components may be powered down during the STANDBY and STOP modes. An electronic device may include a processor that controls the LCD driver circuit. Communications between the processor and LCD driver circuit are prone to errors when the electronic device transitions between modes. However, the LCD segments must function and operate continuously and accurately in each mode without interruption, i.e., the LCD driver circuit needs to continuously provide the required voltage to the LCD segments across mode transitions so that the LCD segments continue to display without any noise or flicker. To ensure that the LCD driver circuit operates correctly without interruption, its electrical behavior needs to be verified.

The operation of the LCD driver circuit also is affected by electrical problems including input/output (I/O) leakage and weak pull ups/pull downs of LCD driver circuit I/O pins connected to the LCD segments. If the leakage from an LCD I/O pin increases beyond a small fraction (for example greater than 5%) of the drive capability of the LCD driver circuit, the voltage provided by the LCD driver circuit to the LCD I/O pin gets disturbed and causes the LCD segment to display incorrectly. A weak pull up is a controllable high resistance path to the supply of an I/O pin of the LCD segment and a weak pull down is a controllable weak resistance path to the ground of the I/O pin of the LCD segment. Weak pull up/pull down may accidentally occur when the electronic device enters the STANDBY mode. Thus, the operation of the LCD driver circuit needs to be verified to identify these problems.

The I/O pins of the LCD segments may sometimes be incorrectly multiplexed with JTAG and other digital functional ports of the electronic device, introducing errors in the voltage provided by the LCD driver circuit to the LCD segments. Moreover, the LCD I/O pins may sometimes get multiplexed with I/O pins of other analog circuits causing the electrical current generated by the LCD driver circuit to be routed to the analog circuits and cause the LCD segments to display erroneously. Further, verification of contrast control of the LCD segments based on the variations in the root mean square (RMS) voltage applied to the LCD segments is crucial as these variations determine the type of glass to be used for the LCD segment display.

Manual verification of each display combination is inefficient and time consuming. For example, a total of 160 display combinations are possible for LCD segments connected by 40 front planes and 4 back planes. To completely verify the operation of the LCD driver circuit, it must be checked to determine whether the LCD driver circuit generates appropriate signals for all possible display combinations, in this case, 160 display combinations. The above-mentioned problems go undetected in most cases due to lack of an efficient method to verify the LCD driver circuits.

Therefore, it would be advantageous to have a system and method that verifies the electrical functional behavior of an LCD driver circuit, does not require manual intervention during the verification process, and overcomes the above-mentioned limitations of existing LCD driver circuit verification systems.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 is a schematic block diagram of an external design verification apparatus for verifying electrical functional behavior of a liquid crystal display (LCD) driver circuit, in accordance with an embodiment of the present invention; and

FIG. 2 is a flow chart depicting a method for verifying electrical functional behavior of an LCD driver circuit using an external design verification apparatus in accordance with an embodiment of the present invention.

### DETAILED DESCRIPTION OF THE INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a method for verifying electrical functional behavior of a liquid crystal display (LCD) driver circuit that is configured to control a plurality of LCDs in an electronic circuit design is provided. The LCD driver circuit is connected to front and back planes of each LCD. The electronic circuit design is stored in a memory and the verification is performed using an external design verification apparatus. The LCD driver circuit is configured to generate a first set of LCD stimuli corresponding to a first set of LCDs, based on a first set of test patterns generated by the external design verification apparatus. A voltage across front and back planes of each LCD of the first set of LCDs is configured based on the first set of LCD stimuli. A first set of root mean square (RMS) voltages are determined based on voltages across the front and back planes of the corresponding first set of LCDs, over at least two successive LCD frame clock pulses. A state of each LCD of the first set of LCDs is verified by comparing the first set of RMS voltages with predetermined threshold voltage values corresponding to the first set of LCD stimuli. The external design verification apparatus verifies the LCD driver circuit based on the state of each LCD.

Various embodiments of the present invention provide a system and method for verifying electrical functional behavior of an LCD driver circuit, using an external design verification apparatus. The LCD driver circuit is connected to a plurality of LCD segments and generates stimuli to apply required voltages across front and back planes of each LCD segment. RMS voltages across the front and back planes of the LCD segments are calculated and used to generate a binary string corresponding to the state of each LCD segment. The binary string is verified against expected values to check if the LCD segments are activated correctly. As opposed to conventional LCD driver circuit verification systems whose functionality is limited to verifying the logical behavior of LCD segments, the external design verification apparatus of the present invention verifies the electrical and functional behavior of the LCD driver circuit by measuring RMS voltages across each LCD segment and identifies electrical and functional errors at the design stage. As the LCD driver circuit and the plurality of LCD segments may be integrated in an electronic device that operates in RUN, STOP and STANDBY modes, the operation of the LCD driver circuit across mode transitions is readily verified by the system of the present invention. The automated verification further eliminates the need for manually verifying the operation of the LCD driver circuit and thus reduces the verification time and improves the accuracy by minimizing human errors. Moreover, any errors identified during the verification may be used to identify design faults including I/O leakage, weak pull ups/pull downs, which are accidentally enabled on the LCD I/O pins, and faulty communication between a processor of the electronic device and the LCD segment, thereby providing the flexibility to rectify the errors at the design stage.

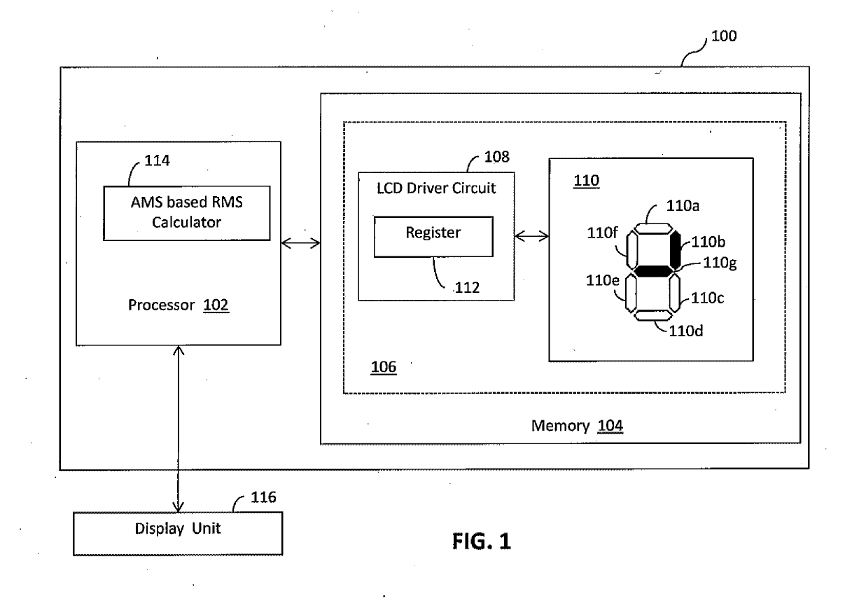

Referring now to FIG. 1, a schematic block diagram illustrating an external design verification apparatus 100 for verifying electrical functional behavior of an LCD driver circuit 108 is shown. The apparatus 100 is described as external, which means that the apparatus is not part of the LCD controller or LCD panel being tested, or vice-versa, that the LCD controller and panel are not part of the verification apparatus 100. The design verification apparatus 100 includes a processor 102 and a memory 104 in communication with the processor 102. The memory 104 is used to store an electronic circuit design 106 that includes the LCD driver circuit 108 and a plurality of LCD segments including first through seventh LCD segments 110a-110g (collectively referred to as LCD segments 110).

The processor 102 and memory 104 comprise a computer system that can range from a stand-alone personal computer to a network of processors and memories, to a mainframe system. The computer system must be able to run mixed signal verification tools that can simulate digital and analog circuits, such as Incisive™ Unified Simulator (IUS) by Cadence Design Systems, Inc. Such tools and computer systems are known to those of skill in the art. The design verification apparatus 100 receives the electronic circuit design 106 as an input and stores the design 106 in the memory 104. Examples of the electronic circuit design 106 include microprocessor, microcontroller unit (MCU), system-on-chip (SOC), and application specific integrated circuit (ASIC) designs. In the embodiment shown, the LCD segments 110 are arranged at intersections of rows and columns (not shown) that represent the front and back planes connecting the LCD segments 110, which is a pattern for a numeric display. However, it will be understood by those of skill in the art that the LCD segments 110 may be arranged in other patterns for other purposes.

The LCD driver circuit 108 includes a register 112 and is connected to the front and back planes of each LCD segment 110. Although only one register 112 is shown and discussed in this embodiment, it will be understood by those of skill in the art that the register 112 could comprise several registers. In various embodiments, the electronic circuit design 106, the LCD driver circuit 108, and the LCD segments 110 are simulated using an analog descriptive language such as SPICE or Verilog A. The entire simulation including digital and analog models runs on a mixed-signal simulator (i.e., the computer system described above). The processor 102 includes an analog mixed signal (AMS) based RMS calculator 114 for measuring RMS voltages across the front and back planes of each LCD segment 110. The calculator 114 is provided in a hardware description language (HDL), preferably Verilog.

The LCD driver circuit 108 generates a first set of LCD stimuli and applies corresponding voltages to the front and back planes of the LCD segments 110. The register 112 is programmed with the LCD stimuli depending on the pattern to be displayed on the LCD segments 110. The apparatus 100 generates AMS verification test patterns used to generate the LCD stimuli. As is known by those of skill in the art, the verifications test patterns are software programs written into the design verification apparatus 100. The LCD stimuli (i.e., the pattern to be displayed) are encoded and stored in the register 112. The LCD driver circuit 108 configures the voltages across the front and back planes of the first set of LCD segments 110 based on the test patterns.

The AMS based RMS calculator 114 calculates the voltages of the first set of LCD segments 110, that is, the RMS voltages are calculated. The calculator 114 constantly monitors the time domain stimuli and calculates the RMS voltages arising due to the stimuli. The RMS voltages preferably are calculated over at least two successive LCD frame clock pulses. Of course, calculating the RMS voltages over more than two successive clock pulses provides for even more accurate calculation. Each calculated RMS voltage is compared with predetermined threshold voltage values to determine a state of a corresponding LCD segment 110. A binary value of 1 is stored in the memory 104 for RMS voltages that fall within a range specified by first predetermined threshold voltage values and a binary value of 0 is stored in the memory 104 for RMS voltages that fall within a range specified by second predetermined threshold voltage values. Based on the stored binary values, a string of 1 s and 0 s corresponding to the first set of LCD segments 110 is generated. The LCD segments with a binary value of 1 are marked as ON and the LCD segments with a binary value of 0 are marked as OFF. Thereafter, the binary string is checked with the expected values defined by the test patterns. If the string of 1 s and 0 s matches the expected values, the LCD driver circuit 108 is deemed to operate correctly. If the string does not match the expected values, the LCD driver circuit 108 is deemed to be operating incorrectly.

In another embodiment of the present invention, a pattern corresponding to the generated and stored binary string may be displayed on a display unit 116. The pattern may be visually observed and compared with the expected values to determine if the LCD driver circuit 108 is operating correctly.

In an example, if the second and seventh LCD segments 110b and 110g (highlighted in FIG. 1) are required to be in the ON state and the first LCD segment 110a and the third through sixth LCD segments 110c-110f are required to be in the OFF state. The design verification apparatus 100 generates test patterns that are loaded in to the register 112. The LCD driver circuit 108 generates corresponding LCD stimuli and applies voltages to the front and the back planes of the LCD segments 110a-110g. The AMS based RMS calculator 114 then calculates the RMS voltages across each LCD segment 110 over two successive LCD frame clock pulses. The calculated RMS voltages then are compared with the first and second predetermined threshold voltage values. If the calculated RMS voltages corresponding to the second and seventh LCD segments 110b and 110g fall within the range of the first predetermined threshold voltage values and the RMS voltages corresponding to the first LCD segment 110a and third through sixth LCD segments 110c-110f fall within the range of the second predetermined threshold voltage values, then a binary value of 1 is assigned to the second and seventh LCD segments 110b and 110g and a binary value of 0 is assigned to the first and third through sixth LCD segments 110a, 110c-110f. The binary values are stored in the memory 104. The binary values form a string of 1 s and 0 s. In this example, the binary string thus obtained is 0100001. If the binary string matches the expected values defined by the test patterns, the LCD driver circuit 108 is deemed to function correctly. A pattern corresponding to the binary string may be displayed on the display unit 116.

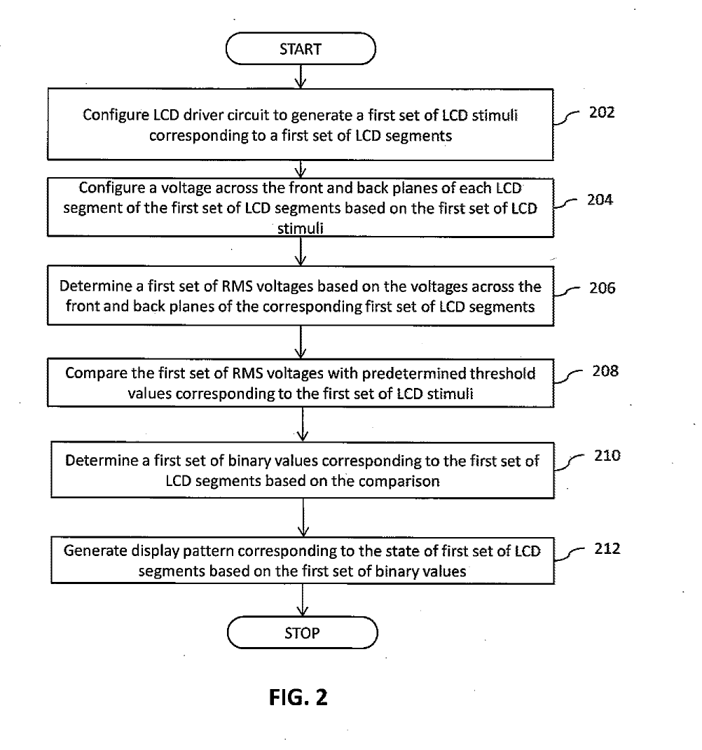

Referring now to FIG. 2, a flow chart depicting a method for verifying electrical functional behavior of the LCD driver circuit 108 using the design verification apparatus 100, in accordance with an embodiment of the present invention, is shown. The steps shown in the flow chart are explained in conjunction with FIG. 1.

The design verification apparatus 100 generates AMS verification test patterns and stores them in the register 112. At step 202, the LCD driver circuit 108 generates LCD stimuli based on the test patterns stored in the register 112. At step 204, the LCD driver circuit 108 configures the voltages across the front and back planes of the first set of LCD segments 110, based on the LCD stimuli. At step 206, RMS voltages across the front and back planes of the first set of LCD segments 110 are calculated by the AMS based RMS calculator 114, preferably over at least two successive LCD frame clock pulses. At step 208, each calculated RMS voltage is compared with predetermined threshold voltage values. At step 210, if the RMS voltage falls within the range of the first predetermined threshold voltage values, a binary value of 1 is assigned and if the RMS voltage falls within the range of second predetermined threshold voltage values, a binary value of 0 is assigned to corresponding LCD segments of the first set of LCD segments 110. Based on the generated binary values, a string of 1 s and 0 s corresponding to the first set of LCD segments 110 is generated. If the string of 1 s and 0 s matches expected values defined by the test patterns, the LCD driver circuit 108 is deemed to function correctly. If the string does not match expected values, the LCD driver circuit 108 is deemed to be functioning erroneously. At step 212, a pattern corresponding to the binary values of the LCD segments is displayed on a display unit 116. The LCD segments 110 that are in ON state are highlighted on the display unit 116.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

1. A design verification apparatus for verifying electrical functional behavior of a liquid crystal display (LCD) driver circuit connected to front and back planes of a plurality of LCD segments, the design verification apparatus comprising:
a processor including a root mean square (RMS) calculator; and
a memory in communication with the processor, wherein the memory is used to store an electronic circuit design of the LCD driver circuit, and wherein the processor:
configures the LCD driver circuit to generate a first set of LCD stimuli corresponding to a first set of LCD segments, based on a first set of test patterns generated by the design verification apparatus;
configures a voltage across the front and back planes of each LCD segment of the first set of LCD segments based on the first set of LCD stimuli;
determines a first set of root mean square (RMS) voltages based on voltages across the front and back planes of the first set of LCD segments using the RMS calculator; and
compares the first set of RMS voltages with predetermined threshold voltage values corresponding to the first set of LCD stimuli to verify a state of each LCD segment, whereby the design verification apparatus verifies the LCD driver circuit based on the state of each LCD segment.

2. The design verification apparatus of claim 1, wherein the RMS calculator comprises an analog and mixed-signal extensions (AMS) based RMS calculator.

3. The design verification apparatus of claim 2, wherein the RMS calculator determines the first set of RMS voltages over at least two successive LCD frame clock pulses.

4. The design verification apparatus of claim 1, wherein the LCD driver circuit comprises one or more registers for generating the first set of LCD stimuli.

5. The design verification apparatus of claim 1, wherein verifying a state of each LCD segment includes determining a first set of binary values corresponding to the first set of LCD segments, based on the comparison between the first set of RMS voltages and the predetermined threshold voltage values.

6. The design verification apparatus of claim 5, wherein the processor further generates a display pattern corresponding to the first set of binary values.

7. The design verification apparatus of claim 6, further comprising a display unit configured to display the display pattern.

8. A method for verifying electrical functional behavior of a liquid crystal display (LCD) driver circuit connected to front and back planes of a plurality of LCD segments, using a design verification apparatus that includes a memory that stores an electronic circuit design of the LCD driver circuit and a processor having a root mean square (RMS) calculator, wherein the memory is in communication with the processor, the method comprising:
configuring the LCD driver circuit to generate a first set of LCD stimuli for a first set of LCD segments based on a first set of test patterns;
configuring a voltage across front and back planes of each LCD segment of the first set of LCD segments based on the first set of LCD stimuli;
determining a first set of root mean square (RMS) voltages based on voltages across the front and back planes of the corresponding first set of LCD segments using the RMS calculator; and
comparing the first set of RMS voltages with predetermined threshold voltage values corresponding to the first set of LCD stimuli to verify a state of each LCD segment, whereby the design verification apparatus verifies the LCD driver circuit design based on the state of each LCD segment.

9. The method of claim 8, wherein the first set of RMS voltages is determined over at least two successive LCD frame clock pulses.

10. The method of claim 8, wherein the first set of LCD stimuli is stored in one or more registers of the LCD driver circuit.

11. The method of claim 8, wherein verifying a state of each LCD segment comprises determining a first set of binary values corresponding to the first set of LCD segments, based on the comparison between the first set of RMS voltages and the predetermined threshold voltage values.

12. The method of claim 11, further comprising generating a display pattern corresponding to the first set of binary values.
